(19) United States
(12) Patent Application Publication
(10) Pub. No.: US 2005/0140019 A1
(43) Pub. Date: Jun. 30, 2005

(54) Semiconductor multilayer wiring substrate of coaxial wiring structure and method of fabricating the same

(76) Inventor: Shoji Watanabe, Nagano-shi (JP)

Correspondence Address: MORGAN & FINNEGAN, L.L.P., 3 WORLD FINANCIAL CENTER, NEW YORK, NY, 10281-2101, US

(21) Appl. No.: 11/015,792

(22) Filed: Dec. 17, 2004

(30) Foreign Application Priority Data
Dec. 24, 2003 (JP) 2003-427956

(51) Int. Cl. H01L 21/00; H01L 21/84; H01L 21/44; H01L 23/48; H01L 23/52; H01L 29/40

(52) U.S. Cl. 257/774; 438/597

(57) ABSTRACT

A multilayer wiring substrate for a semiconductor having a rectangular coaxial wiring structure and a method of fabrication thereof are disclosed, in which a wiring substrate of high density, and free of crosstalk, can be fabricated by press work using a die. A semiconductor wiring substrate comprises an insulating base substrate (2), a first metal layer (3) formed on the base substrate, a plurality of signal patterns (30) formed on the first metal layer through a dielectric layer (5), a second metal layer (36) formed on the signal patterns through a dielectric layer (31), and metal vias (29, 37) for partitioning the adjacent signal patterns (30) through a dielectric layer. The die is used to form the signal patterns and the vias.

### BACKGROUND OF THE INVENTION

1. Field of the Invention

The present invention relates to a semiconductor substrate fabricated by the build-up method and a fabrication method thereof and, in particular, to a multilayer wiring substrate for a semiconductor comprising a coaxial wiring structure intended to prevent crosstalk and to a fabrication method using a molding die to form the wiring pattern.

2. Description of the Related Art

In the conventional method of fabricating a multilayer wiring substrate by the build-up method, it is a common practice to stack a ground layer, a signal layer, etc. in steps, on a base substrate. FIG. 1 shows an example of the conventional process for fabricating a multilayer wiring substrate by the build-up method.

In the first step, a double-face coppered layer plate 1 is prepared. This double-face coppered layer plate 1 includes copper foils 3 and 4 constituting ground layers attached to the two sides of a resin layer 2. In the second step, a dielectric layer 5 is formed on the surface of one of the copper foils. In the third step, via holes (not shown) are formed by a laser, and a copper layer 6 is formed on the dielectric layer 5 by chemical plating. Incidentally, the via holes (not shown) are filled up with a conductive material (not shown) to connect the ground layers 3 and 4 on the two sides of the resin layer 2.

In the fourth step, a resist is coated on the dielectric layer 5 and a resist pattern 7 is formed by exposure and development. Further, an electrolytic copper plating layer 8 is formed on the copper layer 6 exposed by the resist pattern 7 by electrolytic plating with the copper layer 6 as a power feed layer. In the fifth step, the resist pattern 7 is removed, and the portion of the copper layer 6 exposed by the electrolytic copper plating layer 8 is etched off, while at the same time forming wiring patterns 9 with the remaining portion of the electrolytic copper plating layer 8.

In the next sixth step, a dielectric layer 10 is formed on the dielectric layer 5 from which the copper layer 6 has been partially, etched off, and the wiring patterns 9, and is integrated with the lower dielectric layer 6. In the seventh step, a copper layer 11 constituting a ground layer is formed on the dielectric layer 6. Further, via holes or grooves (not shown) are formed by a laser. The via holes are filled up with a conductive material (not shown) to connect the ground layers 11 and 3.

By repeating the first to seventh steps described above, a multilayer wiring substrate having a rectangular coaxial structure in which each signal line having a rectangular cross section is defined by an insulating layer can be formed by the build-up method.

In the conventional method of fabricating a multilayer wiring substrate by forming a plurality of layers in step, the rectangular coaxial wiring structure can be easily fabricated by vias. In view of the fact that the metal wall filled in the via holes and the via grooves are discontinuous along the length of the wiring, however, crosstalk between adjacent signal lines poses a problem. Especially in the portion where signal lines are concentrated at the forward ends thereof, crosstalk cannot be easily prevented by the conventional method of fabricating the multilayer wiring substrate by the build-up method in which the layers are electrically connected by the vias.

In order to achieve a high density on the wiring substrate in the rectangular coaxial wiring structure shown in FIG. 1, for example, the interval t between adjacent signal lines 9 is desirably minimized. Prevention of crosstalk, however, requires the interval t of at least a predetermined length between the signal lines, depending on the specifications and conditions including the frequency of the device. Thus, the possibility of integration and of securing a higher density is limited.

A related conventional technique is disclosed in Japanese Unexamined Patent Publication No. 3-248595, in which a ceramic substrate for high-speed electronic parts including signal lines having a coaxial structure with a ceramic member surrounded by a film, grid or mesh ground wall, uses a ceramic of high mechanical strength for a ceramic member external to the ground wall, while the internal ceramic member around the signal line inside the ground wall uses a ceramic of low dielectric constant.

Japanese Unexamined Patent Publication No. 2003-8178, on the other hand, discloses a method in which the wiring is clearly transferred to the insulating layer of a substrate without using an injection mold or transfer mold, and a recessed circuit die representing the transferred wiring is filled with a wiring conductive paste thereby to fabricate a printed wiring board. Specifically, by pressing a protruded plate corresponding to a printed wiring against the insulating layer of the substrate, the recessed circuit die for wiring is formed on the insulating layer. Then, the conductive paste is filled in the recessed circuit die, and after setting the conductive paste, the surface is polished to expose the insulating layer thereby to form a wiring pattern on the substrate surface.

In the conventional method of fabricating a multilayer wiring board by the build-up method with a plurality of layers formed in steps, the rectangular coaxial wiring structure is fabricated by vias and, therefore, crosstalk between adjacent signal lines poses a problem. Especially, crosstalk in the portion where the signal lines are concentrated cannot be easily eliminated.

### SUMMARY OF THE INVENTION

Accordingly, it is an object of this invention to provide a semiconductor multilayer wiring substrate having a rectangular coaxial wiring structure, and a fabrication method thereof, wherein a wiring is formed not by patterning or etching the resist on a conductive layer but by press work using a transfer die, thereby making it possible to fabricate a rectangular coaxial wiring structure with comparative ease and, especially, to sufficiently prevent crosstalk in the portion where the signal lines are concentrated in a multilayer wiring substrate having a high density.

In order to achieve the above-mentioned object, according to one aspect of this invention, there is provided a semiconductor wiring substrate comprising an insulating base substrate, a first metal layer formed on the base substrate, a plurality of signal patterns formed on the first metal layer through a dielectric layer, a second metal layer formed on the signal patterns through a dielectric layer, and metal vias for defining adjacent ones of the signal patterns through a dielectric layer.

Each of the signal patterns has the upper and lower surfaces thereof defined by the first and second metal layers arranged substantially parallel to each other through a dielectric layer, and the left and right sides thereof defined by the metal vias arranged through a dielectric layer, so that the whole cross section of each signal pattern is defined by a rectangle of metal conductors, through a dielectric layer, thereby to constitute a rectangular coaxial wiring structure.

Further, a plurality of second signal patterns are formed on the second metal layer through a dielectric layer, a third metal layer is formed on the plurality of the second signal patterns through a dielectric layer, and adjacent ones of the second signal patterns are defined by the metal vias through a dielectric layer thereby to constitute a multilayer wiring substrate. In this case, the wiring of the first signal patterns and the second signal patterns are out of phase with each other.

According to a second aspect of the invention, there is provided a method of fabricating a semiconductor wiring substrate, comprising the steps of:
forming a first dielectric layer on a first metal layer formed on at least one of the surfaces of an insulating base substrate;
pressing the first dielectric layer with a first die having a plurality of protrusions for forming at least wiring patterns and vias thereby to form first grooves for defining the wiring patterns and the vias on the first dielectric layer;
filling a metal in the first grooves;
forming a second dielectric layer on the metal filled;
pressing the second dielectric layer with a second die having a plurality of protrusions corresponding to the vias thereby to form second grooves defining the vias on the second dielectric layer; and
filling a metal in the second grooves and on the second dielectric layer.

In this case, a double-face coppered layer plate with copper foils attached to the two sides thereof is used as a base substrate. In the first die, a protrusion to form a via is arranged between the adjacent protrusions for forming wiring patterns. Also, the step of filling the metal in the first grooves includes the steps of forming a thin copper layer constituting a seed layer by nonelectrolytic plating, forming a comparatively thick electrolytic copper plating layer by electrolytic plating with the seed layer as a power feed layer, and polishing the electrolytic copper plating layer until the first dielectric layer is exposed.

Also, the step of filling the metal in the second grooves and on the second dielectric layer includes the steps of forming a thin copper layer constituting a seed layer by nonelectrolytic plating, and forming a comparatively thick electrolytic copper plating layer by electrolytic plating with the seed layer as a power feed layer.

According to still another aspect of the invention, there is provided a method of fabricating a multilayer semiconductor wiring substrate, comprising the steps of:
(a) forming a first dielectric layer on a first metal layer formed on at least one of the surfaces of an insulating base substrate;
(b) pressing the first dielectric layer with a first die having a plurality of protrusions for forming at least wiring patterns and vias thereby to form first grooves for defining the wiring patterns and the vias on the first dielectric layer;
(c) filling a metal in the first grooves;
(d) forming a second dielectric layer on the metal filled;
(e) pressing the second dielectric layer with a second die having a plurality of protrusions corresponding to the vias thereby to form second grooves defining the vias on the second dielectric layer;
(f) filling a metal in the second grooves and on the second dielectric layer; and
(g) forming a dielectric layer on the metal, and repeating the steps (b) to (f).

In this case, the grooves to form the wiring patterns of the first layer and the grooves to form the wiring patterns of the second layer are shifted out of phase with each other by use of dies having the protrusions shifted out of phase with each other.

### BRIEF DESCRIPTION OF THE DRAWINGS

FIG. 1 is a diagram showing a conventional method of fabricating a semiconductor wiring substrate.

FIG. 2 is a diagram showing the steps of the first half process of fabricating a semiconductor wiring substrate using a die according to an embodiment of the invention.

FIG. 3 is a diagram showing the steps of the last half process of fabricating a semiconductor wiring substrate using a die according to an embodiment of the invention.

FIG. 4 is a coaxial wiring structure having upper and lower layers according to an embodiment of the invention.

### DESCRIPTION OF THE PREFERRED EMBODIMENTS

Embodiments of the invention are explained below in detail with reference to the accompanying drawings.

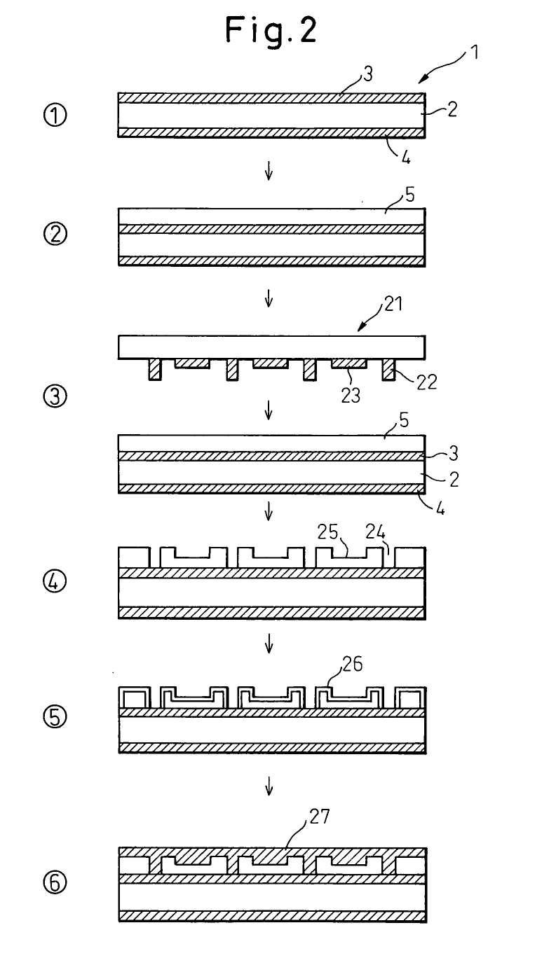

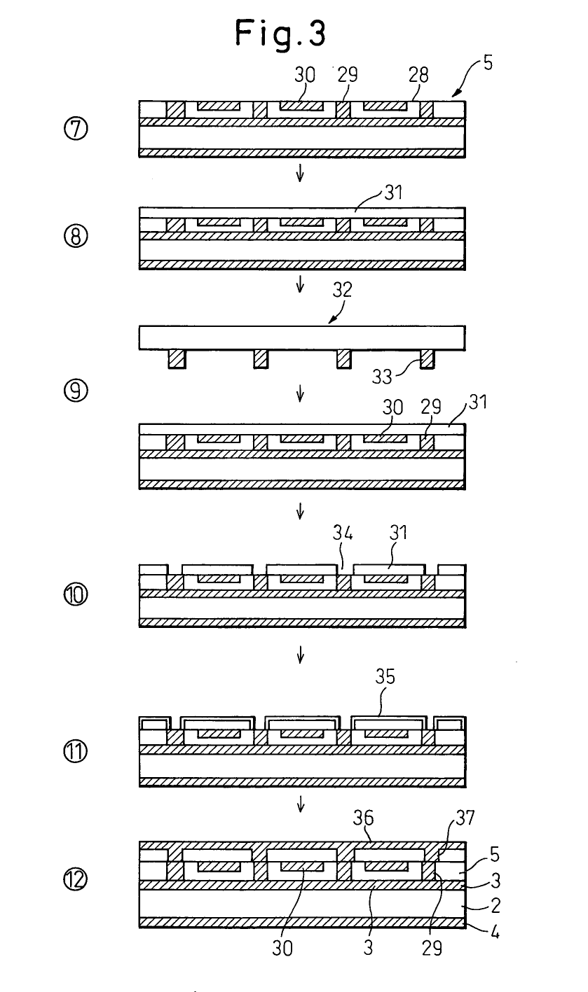

FIGS. 2 and 3 show the steps of fabricating a semiconductor substrate according to an embodiment of the invention. FIG. 2 shows the first half steps and FIG. 3 shows the last half steps.

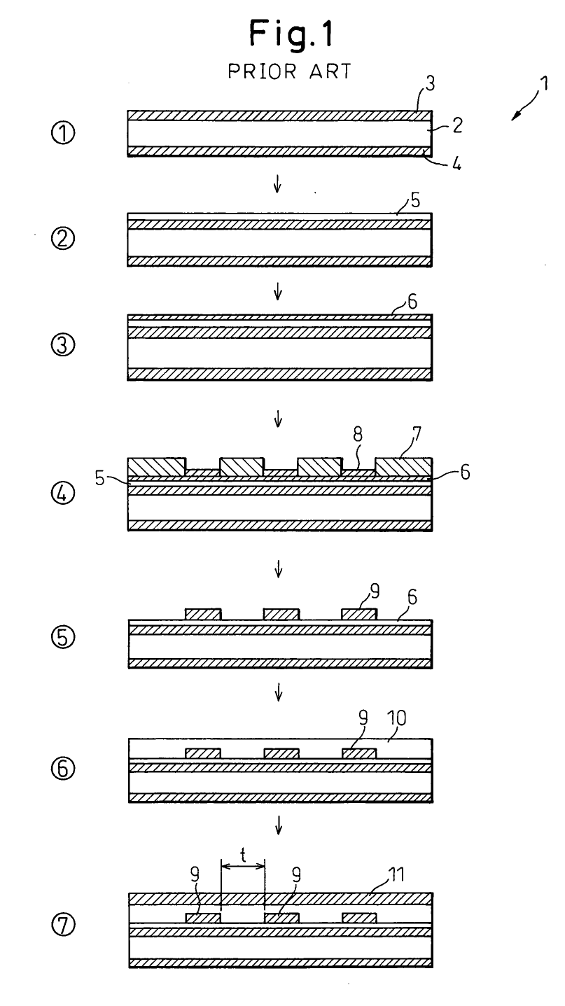

In the first step, a two-side coppered layer plate 1 is prepared. The two-side coppered layer plate 1 includes a resin layer 2 and copper foils 3, 4 constituting ground layers attached on the two sides of the resin layer 2. The copper foil may alternatively be attached only on one side of the resin layer 2. In the second step, a dielectric layer 5 is formed on the surface of one of the copper foils. The first and second steps are similar to the corresponding steps of the prior art shown in FIG. 1, except that a material such as a thermosetting resin adapted to be deformed under pressure when heated in the subsequent steps is used for the dielectric layer 5.

In the third step, according to this invention, a die 21 is used to mold a via or a signal line pattern. In this specification, the “via” is defined as a wire for connecting the layers. The die 21 has protrusions 22 and protrusions 23 corresponding to the vias or the signal line patterns for interlayer connection. The surface of the die 21 having the protrusions 22, 23 is pressed, while being heated, against the dielectric layer 5 of the substrate by press work. The die 21 having the protrusions 22, 23 can be suitably formed of nickel-copper alloy or SUS.

As a result, in the fourth step, a stepped substrate formed with via grooves 24 and signal line pattern grooves 25 corresponding to the protrusions 22 and 23 of the die 21 is formed on the dielectric layer 5 of a thermosetting resin, etc. The via grooves 24 and the signal line pattern grooves 25 are subjected to the preprocessing for plating such as wet processing or plasma processing to remove resin pieces, etc. while exposing the copper layer 3 as a ground layer at the bottom surface of the via grooves 24.

Next, in the fifth step, in order to form a seed layer for electrolytic plating in the next step, a thin copper layer 26 is formed by nonelectrolytic plating, etc. on the dielectric layer 5 having the via grooves 24 and the signal line pattern grooves 25.

In the sixth step, a comparatively thick electrolytic copper plating layer 27 is formed by electrolytic plating with the copper layer 26 formed in the preceding step as a seed layer. Copper is deposited for this electrolytic copper plating layer 27 until the via grooves 24 and the signal line pattern grooves 25 are filled up. As a result, the dielectric layer 5 is wholly covered with the electrolytic copper plating layer 27 without partial exposure.

Next, in the seventh step, the surface of the electrolytic copper plating layer 27 is polished, so that the electrolytic copper plating layer 27 is removed to such a degree as to expose a part 28 of the dielectric layer 5 except for the portion corresponding to the via grooves 24 and the signal line pattern grooves 25. The electrolytic copper plating layer 27 remains as vias 28 and signal line patterns 29 in the portion corresponding to the via grooves 24 and the signal line pattern grooves 25.

In the eighth step, a dielectric layer 31 is further formed on the polished surface 28 of the dielectric layer 5 and the vias 29 and the signal line patterns 30 and integrated with the lower dielectric layer 5. As in the case described above, the dielectric layer 31 is formed of a thermosetting resin or the like material adapted to be deformed under pressure with heat in the subsequent steps.

Next, in the ninth step, a die 32 is used to mold a part of the vias. This die 32 has protrusions 33 at positions corresponding to the vias 29. The side of the die 32 having the protrusions 33 is pressed, while being heated, against the dielectric layer 31 by press work. The die 32 having the protrusions 33, like the die 21 described above, can be suitably produced from nickel-copper alloy or SUS.

Thus, in the tenth step, via grooves 34 corresponding to the protrusions 33 of the die 32 are formed in steps on the dielectric layer 31 of a thermosetting resin or the like. This via grooves 34, as in the case described above, is subjected to the wet processing or the plasma processing as a process before plating thereby to remove resin pieces, etc. while at the same time exposing the upper surface of the vias 28 already formed on the bottom surface of the via grooves 24.

In the 11th step, in order to form a seed layer for the electrolytic plating in the next step, a thin copper layer 35 is formed by nonelectrolytic plating or the like on the dielectric layer 31 having the via grooves 34. As a result, the whole surface of the dielectric layer 31 including the upper surface of the vias 28 exposed from the via grooves 34 and the inner wall surface of the via grooves 34 is formed with a thin copper layer 35 by nonelectrolytic plating or the like as a seed layer for electrolytic plating in the next step.

Then, in the 12th step, an electrolytic copper plating layer 36 is formed by electrolytic plating using the copper layer 35 formed in the previous step as a seed layer. Copper is deposited for the electrolytic copper plating layer 36 until the via grooves 34 are filled up. As a result, the whole surface of the dielectric layer 5 is covered with the electrolytic copper plating layer 35 without partial exposure.

The process of the second to 12th steps is repeated to fabricate a multilayer wiring substrate for the semiconductor having a coaxial wiring structure.

In this way, a rectangular coaxial structure is produced, in which each signal line pattern 30 with a rectangular cross section has the lower portion thereof defined by the copper foil 3, the side portions thereof defined by the vias 29, 37, and the upper portion thereof defined by the electrolytic copper plating layer 36, each through an dielectric layer of an insulating material. Especially, the whole periphery of the cross section of each signal line pattern 30 is fully defined by a rectangle and, therefore, crosstalk which otherwise might be caused by interference between adjacent signal patterns 30 can be sufficiently prevented. Also, the interval between adjacent signal patterns 3 can be set to a smaller length, thereby contributing to a higher density and higher integration of the semiconductor device.

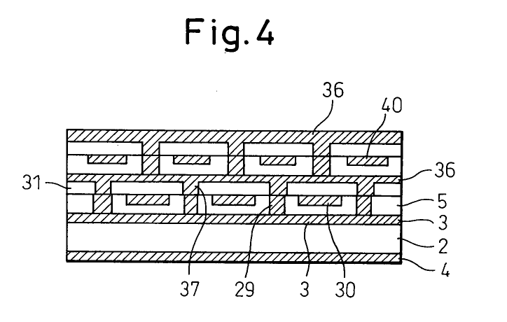

FIG. 4 shows an embodiment in which the coaxial wiring structure of a second layer is formed on the coaxial wiring structure of the first layer described above. A plurality of the signal patterns 30 of the first layer and a plurality of the signal patterns 40 of the second layer have the wiring thereof desirably out of phase with each other. In this way, crosstalk between adjacent wires can be prevented and a higher wiring density achieved.

The embodiments of the invention are described above with reference to the accompanying drawings. This invention, however, is not limited to those embodiments, but variously modifiable without departing from the spirit and scope of the invention.

It will thus be understood from the foregoing description that according to this invention, there is provided a method of fabricating a multilayer wiring substrate having a rectangular coaxial wiring structure, in which the method of forming the wiring by plating or etching after patterning the resist on the conductive layer is replaced by the method of conducting the press work using a die. As a result, a multilayer wiring substrate having a rectangular coaxial wiring structure can be fabricated with comparative ease, and crosstalks can be prevented sufficiently, thereby producing a multilayer wiring substrate for a semiconductor suitable for high density and high integration. Also, the connections around the wiring become more free, and the freedom of wiring design is improved, thereby making possible an ideal wiring design of a coaxial system.

1. A semiconductor wiring substrate comprising an insulating base substrate, a first metal layer formed on the base substrate, a plurality of signal patterns formed on the first metal layer through a dielectric layer, a second metal layer formed on the signal pattern through a dielectric layer, and metal vias for defining adjacent signal patterns through a dielectric layer.

2. A semiconductor wiring substrate according to claim 1, wherein each of the signal patterns has the upper and lower surfaces thereof defined by the first and second metal layers arranged substantially parallel to each other through a dielectric layer, and has the left and right sides thereof defined by the metal vias arranged through a dielectric layer, so that the whole cross section of each signal pattern is defined by a rectangle of metal conductors through a dielectric layer thereby to define a rectangular coaxial wiring structure.

3. A semiconductor wiring substrate according to claim 1, wherein a plurality of second signal patterns are formed on the second metal layer through a dielectric layer, a third metal layer is formed on the plurality of the second signal patterns through a dielectric layer, and adjacent ones of the second signal patterns are defined by the metal vias through a dielectric layer thereby to constitute a multilayer wiring substrate.

4. A semiconductor wiring substrate according to claim 3, wherein said plurality of the first signal patterns and said plurality of the second signal patterns have the wiring thereof out of phase with each other.

5. A method of fabricating a semiconductor wiring substrate, comprising the steps of:
forming a first dielectric layer on a first metal layer formed on at least one of the surfaces of an insulating base substrate;
pressing the first dielectric layer with a first die having a plurality of protrusions for forming at least wiring patterns and vias thereby to form first grooves for defining wiring patterns and vias on the first dielectric layer;
filling a metal in the first grooves;
forming a second dielectric layer on the metal filled;
pressing the second dielectric layer with a second die having a plurality of protrusions corresponding to the vias thereby to form second grooves defining the vias on the second dielectric layer; and
filling a metal in the second grooves and on the second dielectric layer.

6. A method of fabricating a semiconductor wiring substrate according to claim 5,
wherein said first die has the protrusions to form said vias, said protrusions are arranged between the adjacent protrusions to form the adjacent wiring patterns.

7. A method of fabricating a semiconductor wiring substrate according to claim 5,
wherein a two-side coppered layer plate with a copper foil attached on the two sides thereof is used as a base substrate.

8. A method of fabricating a semiconductor wiring substrate according to claim 5,
wherein the step of filling the metal in the first grooves includes the steps of forming a thin copper layer constituting a seed layer by nonelectrolytic plating, forming a comparatively thick electrolytic copper plating layer by electrolytic plating with the seed layer as a power feed layer, and polishing the electrolytic copper plating layer until the first dielectric layer is exposed.

9. A method of fabricating a semiconductor wiring substrate according to claim 5,
wherein the step of filling the metal in the second grooves and on the second dielectric layer includes the steps of forming a thin copper layer constituting a seed layer by nonelectrolytic plating, and forming a comparatively thick electrolytic copper plating layer by electrolytic plating with the seed layer as a power feed layer.

10. A method of fabricating a multilayer semiconductor wiring substrate, comprising the steps of:
(a) forming a first dielectric layer on a first metal layer formed on at least one of the surfaces of an insulating base substrate;
(b) pressing the first dielectric layer with a first die having a plurality of protrusions for forming at least wiring patterns and vias thereby to form first grooves for defining the wiring patterns and the vias on the first dielectric layer;
(c) filling a metal in the first grooves;
(d) forming a second dielectric layer on the metal filled;
(e) pressing the second dielectric layer with a second die having a plurality of protrusions corresponding to the vias thereby to form second grooves defining the vias on the second dielectric layer;
(f) filling a metal in the second grooves and on the second dielectric layer; and
(g) forming a dielectric layer on the metal, and repeating the steps (b) to (f).

11. A method of fabricating a semiconductor wiring substrate according to claim 10,
wherein a first die used for the press work for forming the grooves to form the wiring patterns of the first layer and a second die used for the press work for forming the grooves to form the wiring patterns of the second layer have protrusions which are out of phase from each other thereby to form the wiring patterns of the first and second layers out of phase with each other.
